(19) United States
(12) Patent Application Publication
(10) Pub. No.: US 2007/0256825 A1
(43) Pub. Date: Nov. 8, 2007

(54) Methodology for the liquid cooling of heat generating components mounted on a daughter card/expansion card in a personal computer through the use of a remote drive bay heat exchanger with a flexible fluid interconnect

(76) Inventors: Bruce R. Conway, La Honda, CA (US); Richard Grant Brewer, Foster City, CA (US); Paul Tsao, Los Altos, CA (US); James Hom, Redwood City, CA (US); Douglas E. Werner, Santa Clara, CA (US); Peng Zhou, Albany, CA (US); Girish Upadhya, Austin, TX (US); Madhav Datta, Milpitas, CA (US); Ali Firouzi, Los Altos, CA (US); Fredric Landry, Montreal (CA)

Correspondence Address: HAVERSTOCK & OWENS LLP, 162 N WOLFE ROAD, SUNNYVALE, CA, 94086, US

(21) Appl. No.: 11/800,303

(22) Filed: May 3, 2007

Related U.S. Application Data
(60) Provisional application No. 60/797,955, filed on May 4, 2006.

(51) Int. Cl. G05D 23/00; H01L 23/467

(52) U.S. Cl. 165/292; 165/121

(57) ABSTRACT

A cooling system includes a cooling unit configured to fit within a single drive bay of a personal computer. The cooling unit includes a fluid-to-air heat exchanger, an air mover, a pump, fluid lines, and control circuitry. The cooling system also includes a cooling loop configured to be coupled to one or more heat generating devices. The cooling loop includes the pump and the fluid-to-air heat exchanger from the cooling unit, and at least one heat exchanger coupled together via flexible fluid lines. The heat exchanger is thermally coupled to the heat generating device. The cooling unit is configured to maintain noise below a specified acoustical specification. To meet this acoustical specification, the size, position, and type of the components within the cooling unit are specifically configured.

### RELATED APPLICATIONS

This patent Application claims priority under 35 U.S.C. 119 (e) of the co-pending U.S. Provisional Patent Application Ser. No. 60/797,955 filed May 4, 2006, and entitled “LIQUID COOLING THROUGH REMOTE DRIVE BAY HEAT EXCHANGER”. The Provisional Patent Application, Ser. 60/797,955 filed May 4, 2006, and entitled “LIQUID COOLING THROUGH REMOTE DRIVE BAY HEAT EXCHANGER” is also hereby incorporated by reference.

### FIELD OF THE INVENTION

The invention relates to a method of and apparatus for cooling a heat generating device in general, and specifically, to a method of and apparatus for cooling heat generating devices within a personal computer using a remote drive bay cooling unit and flexible fluid interconnect.

### BACKGROUND OF THE INVENTION

Cooling of high performance integrated circuits with high heat dissipation is presenting significant challenge in the electronics cooling arena. Conventional cooling with heat pipes and fan mounted heat sinks are not adequate for cooling chips with every increasing wattage requirements.

A particular problem with cooling integrated circuits within personal computers is that more numerous and powerful integrated circuits are configured within the same size or small personal computer chassis. As more powerful integrated circuits are developed, each with an increasing density of heat generating transistors, the heat generated by each individual integrated circuit continues to increase. Further, more and more integrated circuits, such as graphics processing units, microprocessors, and multiple-chip sets, are being added to personal computers. Still further, the more powerful and more plentiful integrated circuits are being added to the same, or small size personal computer chassis, thereby increasing the per unit heat generated for these devices. In such configurations, conventional personal computer chassis' provide limited dimensions within which to provide an adequate cooling solution. Conventionally, the integrated circuits within a personal computer are cooled using a heat sink and a large fan that blows air over the heat sink, or simply by blowing air directly over the circuit boards containing the integrated circuits. However, considering the limited free space within the personal computer chassis, the amount of air available for cooling the integrated circuits and the space available for conventional cooling equipment, such as heat sinks and fans, is limited.

Closed loop liquid cooling presents alternative methodologies for conventional cooling solutions. Closed loop liquid cooling solutions more efficiently reject heat to the ambient than air cooling solutions.

Conventional personal computers are being developed with ever increasing configurability, including the ability to upgrade existing components and to add new ones. With each upgrade and/or addition, increasing cooling demands are placed on the existing cooling system. Most existing cooling systems are left as is with the expectation that their current cooling capacity is sufficient to accommodate the added cooling load placed by the new or upgraded components. Alternatively, existing cooling systems are completely replaced with a new cooling system with a greater cooling capacity. Existing cooling systems can also be upgraded, but this requires splicing into the existing cooling system to add additional cooling components. In the case of liquid cooling systems, an upgrade requires opening a sealed cooling system to add capacity. Such a process is labor intensive and requires the existing liquid based cooling system to be removed from the personal computer to avoid possible damage to the internal electronic components due to fluid leaks.

What is needed is a more efficient cooling methodology for cooling integrated circuits within a personal computer. What is also needed is a more space-efficient cooling methodology to better utilize the limited space within a personal computer. What is still further needed is a cooling methodology that is scalable to meet the scalable configurations of today's personal computers.

### SUMMARY OF THE INVENTION

A cooling system includes a cooling unit configured to fit within a single drive bay of a personal computer. The cooling unit includes a fluid-to-air heat exchanger, an air mover, a pump, fluid lines, and control circuitry. The cooling system also includes a cooling loop configured to be coupled to one or more heat generating devices. The cooling loop includes the pump and the fluid-to-air heat exchanger from the cooling unit, and at least one heat exchanger coupled together via flexible fluid lines. The heat exchanger is thermally coupled to the heat generating device such that fluid flowing through the heat exchanger is heated by heat transferred from the heat generating device. The heated fluid is pumped from the heat exchanger to the fluid-to-air heat exchanger within the cooling unit. The air mover forces air through the fluid-to-air heat exchanger thereby cooling the heated fluid therethrough. The cooling unit is configured to maintain noise below a specified acoustical specification. To meet this acoustical specification, the size, position, and type of the components within the cooling unit are specifically configured.

In one aspect, a cooling system for cooling one or more heat generating devices within a personal computer is disclosed. The cooling system includes a cooling unit that has a housing configured to fit within a single drive bay of the personal computer, a fluid-to-air heat exchanging device positioned at a first end of the housing, an air mover positioned at a second end of the housing, a pump positioned within the housing, a plurality of fluid lines coupled to the pump and to the fluid-to-air heat exchanging device, and a control circuit positioned within the housing and coupled to the air mover and to the pump. The cooling system also includes one or more heat exchanging devices coupled to the plurality of fluid lines and to the one or more heat generating devices, wherein the one or more heat exchanging devices, the plurality of fluid lines, the pump, and the fluid-to-air heat exchanging device form a closed fluid loop, wherein the cooling unit is configured to operate at less than or equal to approximately 42 decibels and the cooling unit has a thermal resistance of less than or equal to 0.30 degrees Celsius per watt. The control circuit can be configured to regulate a first operation rate of the air mover and a second operation rate of the pump. The plurality of fluid lines are configured to input heated fluid into the cooling unit and to output cooled fluid from the cooling unit. The cooling system can also include a fluid reservoir coupled to the closed fluid loop. In some embodiments, cooling unit is configured to operate at less than or equal to approximately 38 decibels. In some embodiments, the thermal resistance of the cooling unit is less than or equal to approximately 0.20 degrees Celsius per watt. The air mover can be a two-axial blower. In this case, two-axial blower is configured to generate a vacuum inside the housing relative to the ambient. The two-axial blower can include a first opening on a top surface of the blower and a second opening on a side surface of the blower. In some embodiments, the blower is configured to draw air into the first opening and to force air out of the second opening. In other embodiments, the blower is configured to draw air into the second opening and to force air out of the first opening. In one configuration, the air mover is separated by at least approximately 25 millimeters from the fluid-to-air heat exchanging device, a height of the air mover is approximately 25 millimeters, and the air mover includes an impeller with a diameter of at least approximately 100 millimeters. The pump can be configured as an in-line pump having a pump inlet and a pump outlet configured in opposite sides of the pump. In some embodiments, the fluid-to-air heat exchanging device comprises a radiator. The housing preferably includes vents in a first side proximate the first end of the housing and a housing opening in a second side proximate the second end of the housing. The housing can include a control interface coupled to the control circuit. The housing can also include a power interface coupled to the air mover, the pump, and the control circuit. The control circuit can be configured to provide pulse width modulation control to the air mover. In some embodiments, each of the plurality of fluid lines has a water vapor transmission rate of less than or equal to 0.30 grams per centimeter at 65 degrees Celsius.

In another aspect, the cooling unit includes a housing configured to fit within a single drive bay of a personal computer, wherein the housing includes vents in a first end of the housing and a housing opening in a second end of the housing, a fluid-to-air heat exchanging device positioned at the first end of the housing, a two-axial blower positioned at the second end of the housing, wherein the blower includes a first opening on a top surface of the blower and a second opening on a side surface of the blower aligned with the housing opening, a pump positioned within the housing, a plurality of fluid lines coupled to the pump and to the fluid-to-air heat exchanging device, wherein the plurality of fluid lines are configured to input heated fluid into the cooling unit and to output cooled fluid from the cooling unit, and a control circuit positioned within the housing and coupled to the air mover and to the pump.

Other features and advantages of the present invention will become apparent after reviewing the detailed description of the embodiments set forth below.

### BRIEF DESCRIPTION OF THE DRAWINGS

FIG. 1 illustrates a perspective view from the top and front of an exemplary cooling unit configured to fit within a single drive bay of a personal computer.

FIG. 2 illustrates a perspective view from the top and back of the cooling unit of FIG. 1.

FIG. 3 illustrates a block diagram of an exemplary cooling loop including the cooling unit of FIG. 1.

The present invention is described relative to the several views of the drawings. Where appropriate and only where identical elements are disclosed and shown in more than one drawing, the same reference numeral will be used to represent such identical elements.

### DETAILED DESCRIPTION OF THE PRESENT INVENTION

Embodiments of the present invention are directed to a scalable and modular cooling system that removes heat generated by one or more heat generating devices within a personal computer. The heat generating devices include, but are not limited to, one or more central processing units (CPU), a chipset used to manage the input/output of one or more CPUs, one or more graphics processing units (GPUs), and/or one or more physics processing units (PPUs), mounted on a motherboard, a daughter card, and/or a PC expansion card. The cooling system can also be used to cool power electronics, such as mosfets, switches, and other high-power electronics requiring cooling. In general, the cooling system described herein can be applied to any electronics sub-system that includes a heat generating device to be cooled. For simplicity, any sub-system installed within the personal computer that includes one or more heat generating devices to be cooled is referred to as a PC card.

A cooling unit is configured to fit within a single PC drive bay. As new or increased cooling needs are required, such as the addition of a new PC card, an additional cooling unit can be added. The cooling unit fits within the PC drive bay and is coupled to one or more remotely located heat generating devices within the PC. Additionally, already installed PC cards can be swapped for new or upgraded PC cards with corresponding alterations to the cooling system.

The cooling unit is preferably configured to fit within a single drive bay of a personal computer chassis. Alternatively, the cooling unit is configured to fit within a drive bay of any electronics system that includes heat generating devices to be cooled. A cooling system includes the cooling unit and an independent fluid-based cooling loop. The cooling unit includes a fluid-to-air heat exchanger, an air mover, a pump, fluid lines, and control circuitry. The air mover is preferably a two-axial blower. The air mover draws air into the cooling unit and through the fluid-to-air heat exchanger.

The cooling loop includes the fluid-to-air heat exchanger and the pump within the cooling unit, and at least one other heat exchanger. The components in the cooling loop are coupled via flexible fluid lines. In some embodiments, the fluid-to-air heat exchanger is a radiator. As described herein, reference to a radiator is used. It is understood that reference to a radiator is representative of any type of conventional fluid-to-air heat exchanging system unless specific characteristics of the radiator are explicitly referenced. Each of the other heat exchangers in the cooling loop are coupled to either another heat exchanger, which is part of a different cooling loop or device, or to a heat generating device.

PC Cards.

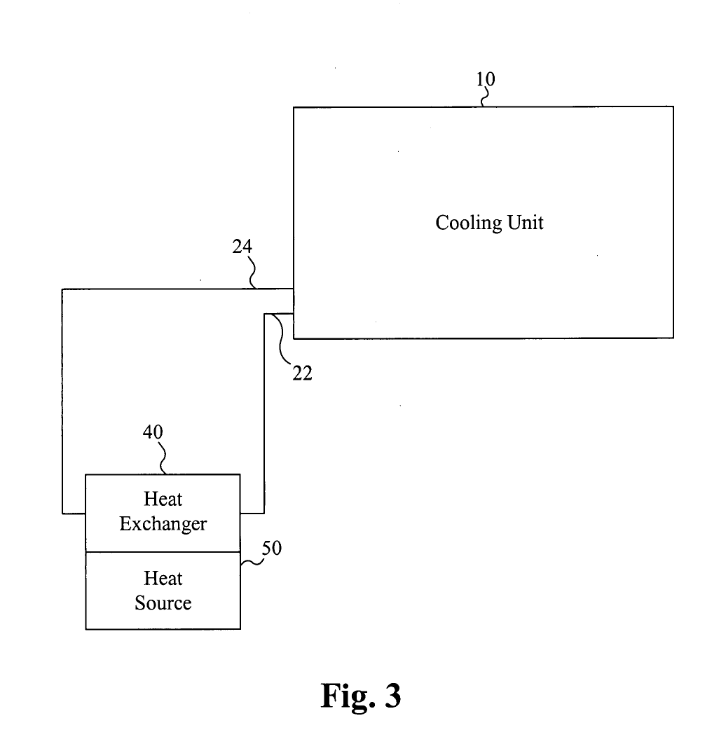

In an alternative embodiment, an intermediary cooling loop is coupled between the cooling loop and the heat source 50. The intermediate cooling loop is independent of the cooling loop coupled to the cooling unit 10. The intermediate cooling loop can include a first heat exchanger coupled to the heat exchanger 40 of the other cooling loop, a pump, and at least one other second heat exchanger, all coupled via fluid lines. The second heat exchanger is coupled to the heat source 50 in a manner similar to the heat exchanger 40 coupled to the heat source 50 in FIG. 3. The heat exchanger 40 is similarly coupled to the first heat exchanger in the intermediate cooling loop, thereby forming a thermal interface between the two. The intermediate cooling loop can include more than one such second heat exchanger coupled in series or parallel.

Heat generated by the heat source 50 is transferred to fluid flowing through the intermediate cooling loop, which in turn is transferred to fluid flowing through the cooling loop coupled to the cooling unit 10. An exemplary method of transferring heat from a heat generating device to a fluid-to-air heat exchanger via two or more independent fluid cooling loops is described in detail in the co-owned U.S. patent application Ser. No. 11/707,350, filed Feb. 16, 2007, and entitled “Liquid Cooling Loops for Server Applications”, which is hereby incorporated in its entirety by reference.

In yet another alternative embodiment, the heat exchanger 40 of the cooling loop is coupled to a thermal bus, where the thermal bus is capable of interfacing with a plurality of heat exchangers from a plurality of different cooling loops. Such a configuration is described in the co-owned U.S. patent application Ser. No. ______ (Cool 05201), filed on Apr. 6, 2007, and entitled “Methodology of Cooling Multiple Heat Sources in a Personal Computer Through the Use of Multiple Fluid-based Heat Exchanging Loops Coupled via Modular Bus-type Heat Exchangers”, which is hereby incorporated in its entirety by reference.

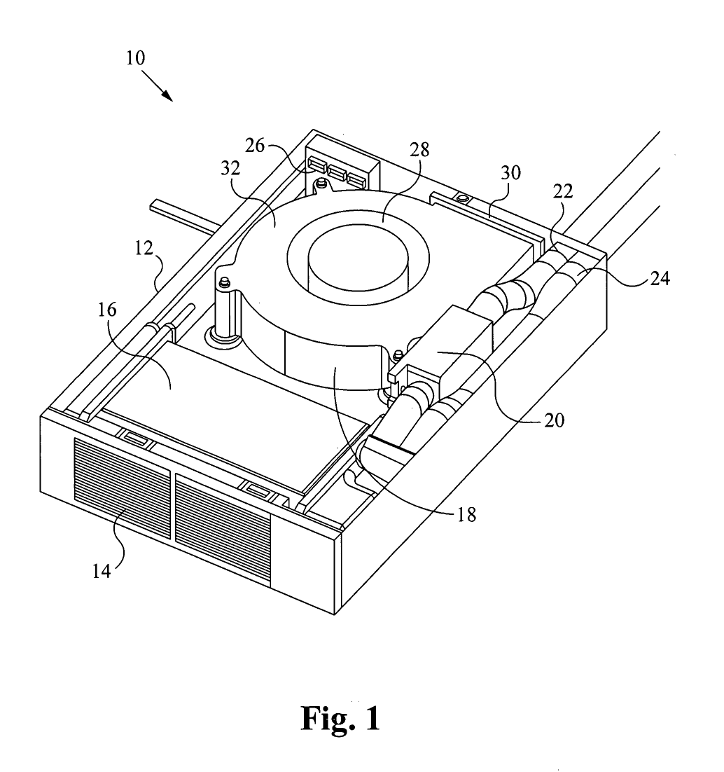

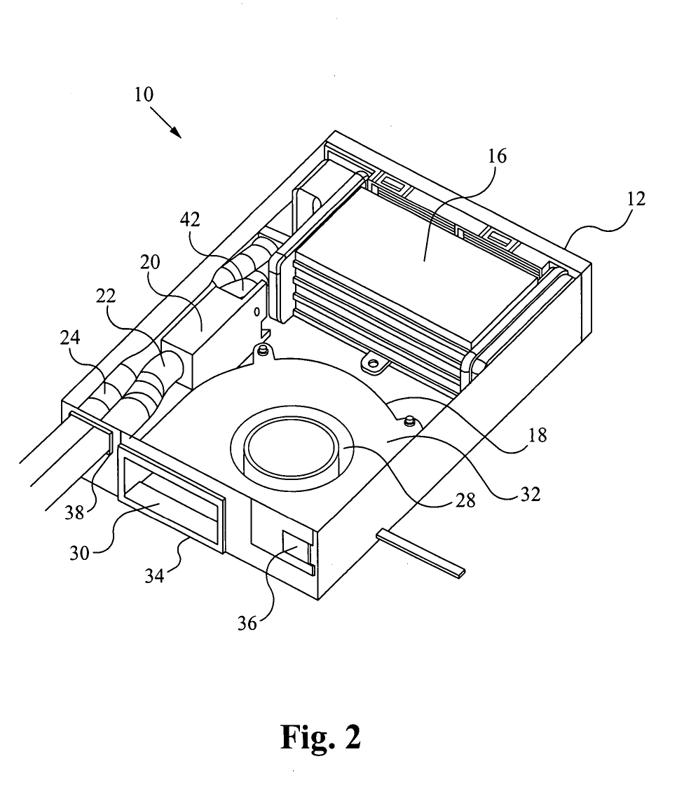

It is apparent to one skilled in the art that the present cooling system is not limited to the components shown in FIG. 1-3 and alternatively includes other components and devices. For example, although not shown in FIG. 3, the cooling loop can also include a fluid reservoir. The fluid reservoir accounts for fluid loss over time due to permeation.

In some embodiments, the cooling system is configured to cool each heat generating device included within a PC chassis. In other embodiments, the cooling system is configured to cool only select heat generating devices, or only a single heat generating device, while other heat generating devices are left to be cooled by other or complimentary means.

The present invention has been described in terms of specific embodiments incorporating details to facilitate the understanding of the principles of construction and operation of the invention. Such reference herein to specific embodiments and details thereof is not intended to limit the scope of the claims appended hereto. It will be apparent to those skilled in the art that modifications may be made in the embodiment chosen for illustration without departing from the spirit and scope of the invention.

What is claimed is:

1. A cooling unit for cooling a heat generating device in a personal computer having a heat exchanger for coupling to the heat generating device and a plurality of fluid lines for coupling the heat exchanger to the cooling unit, the cooling unit comprising:
a. a housing configured to fit within a single drive bay of a personal computer;
b. a fluid-to-air heat exchanging device positioned at a first end of the housing;
c. an air mover positioned at a second end of the housing;
d. a pump positioned within the housing;
e. the plurality of fluid lines coupled to the pump and to the fluid-to-air heat exchanging device, wherein the plurality of fluid lines are configured to input heated fluid into the cooling unit and to output cooled fluid from the cooling unit; and
f. a control circuit coupled to the air mover and to the pump, wherein the control circuit is configured to regulate a first operation rate of the air mover and a second operation rate of the pump,
wherein the cooling unit is configured to operate at less than or equal to approximately 42 decibels and the cooling unit has a thermal resistance of less than or equal to 0.30 degrees Celsius per watt.

2. The cooling unit of claim 1 wherein the cooling unit is configured to operate at less than or equal to approximately 38 decibels.

3. The cooling unit of claim 1 wherein the thermal resistance of the cooling unit is less than or equal to approximately 0.20 degrees Celsius per watt.

4. The cooling unit of claim 1 wherein the air mover comprises a two-axial blower.

5. The cooling unit of claim 4 wherein the two-axial blower is configured to generate a vacuum inside the housing relative to the ambient.

6. The cooling unit of claim 4 wherein the two-axial blower includes a first opening on a top surface of the blower and a second opening on a side surface of the blower.

7. The cooling unit of claim 6 wherein the blower is configured to draw air into the first opening and to force air out of the second opening.

8. The cooling unit of claim 6 wherein the blower is configured to draw air into the second opening and to force air out of the first opening.

9. The cooling unit of claim 1 wherein the air mover is separated by at least approximately 25 millimeters from the fluid-to-air heat exchanging device.

10. The cooling unit of claim 1 wherein the pump comprises an in-line pump having a pump inlet and a pump outlet configured on opposite sides of the pump.

11. The cooling unit of claim 1 wherein the fluid-to-air heat exchanging device comprises a radiator.

12. The cooling unit of claim 1 wherein the housing includes vents in a first side proximate the first end of the housing.

13. The cooling unit of claim 1 wherein the housing includes a housing opening in a second side proximate the second end of the housing.

14. The cooling unit of claim 1 wherein the housing includes a control interface coupled to the control circuit.

15. The cooling unit of claim 1 wherein the housing includes a power interface coupled to the air mover, the pump, and the control circuit.

16. The cooling unit of claim 1 wherein a height of the air mover is approximately 25 millimeters and the air mover includes an impeller with a diameter of at least approximately 100 millimeters.

17. The cooling unit of claim 1 wherein the control circuit is configured to provide pulse width modulation control to the air mover.

18. The cooling unit of claim 1 wherein each of the plurality of fluid lines has a water vapor transmission rate of less than or equal to 0.30 grams per centimeter at 65 degrees Celsius.

19. A cooling unit for cooling a heat generating device in a personal computer having a heat exchanger for coupling to the heat generating device and a plurality of fluid lines for coupling the heat exchanger to the cooling unit, the cooling unit comprising:
a. a housing configured to fit within a single drive bay of a personal computer, wherein the housing includes vents in a first end of the housing and a housing opening in a second end of the housing;
b. a fluid-to-air heat exchanging device positioned at the first end of the housing;
c. a two-axial blower positioned at the second end of the housing, wherein the blower includes a first opening on a top surface of the blower and a second opening on a side surface of the blower aligned with the housing opening;
d. a pump positioned within the housing;
e. the plurality of fluid lines coupled to the pump and to the fluid-to-air heat exchanging device, wherein the plurality of fluid lines are configured to input heated fluid into the cooling unit and to output cooled fluid from the cooling unit; and
f. a control circuit coupled to the air mover and to the pump,
wherein the cooling unit is configured to operate at less than or equal to approximately 42 decibels and the cooling unit has a thermal resistance of less than or equal to 0.30 degrees Celsius per watt.

20. The cooling unit of claim 19 wherein the cooling unit is configured to operate at less than or equal to approximately 38 decibels.

21. The cooling unit of claim 19 wherein the thermal resistance of the cooling unit is less than or equal to approximately 0.20 degrees Celsius per watt.

22. The cooling unit of claim 19 wherein the control circuit is configured to regulate a first operation rate of the blower and a second operation rate of the pump.

23. The cooling unit of claim 19 wherein the blower is configured to generate a vacuum inside the housing relative to the ambient.

24. The cooling unit of claim 19 wherein the blower is configured to draw air into the first opening and to force air out of the second opening.

25. The cooling unit of claim 19 wherein the blower is configured to draw air into the second opening and to force air out of the first opening.

26. The cooling unit of claim 19 wherein the blower is separated by at least approximately 25 millimeters from the fluid-to-air heat exchanging device.

27. The cooling unit of claim 19 wherein the pump comprises an in-line pump having a pump inlet and a pump outlet configured on opposite sides of the pump.

28. The cooling unit of claim 19 wherein the fluid-to-air heat exchanging device comprises a radiator.

29. The cooling unit of claim 19 wherein the housing includes a control interface coupled to the control circuit.

30. The cooling unit of claim 19 wherein the housing includes a power interface coupled to the air mover, the pump, and the control circuit.

31. The cooling unit of claim 19 wherein a height of the blower is approximately 25 millimeters and the blower includes an impeller with a diameter of at least approximately 100 millimeters.

32. The cooling unit of claim 19 wherein the control circuit is configured to provide pulse width modulation control to the blower.

33. The cooling unit of claim 19 wherein each of the plurality of fluid lines has a water vapor transmission rate of less than or equal to 0.30 grams per centimeter at 65 degrees Celsius.

34. A cooling system for cooling one or more heat generating devices within a personal computer, the cooling system comprising:
a. a cooling unit comprising:
i. a housing configured to fit within a single drive bay of the personal computer;
ii. a fluid-to-air heat exchanging device positioned at a first end of the housing;
iii. an air mover positioned at a second end of the housing;
iv. a pump positioned within the housing;
v. a plurality of fluid lines coupled to the pump and to the fluid-to-air heat exchanging device; and
vi. a control circuit positioned within the housing and coupled to the air mover and to the pump; and
b. one or more heat exchanging devices coupled to the plurality of fluid lines and to the one or more heat generating devices, wherein the one or more heat exchanging devices, the plurality of fluid lines, the pump, and the fluid-to-air heat exchanging device form a closed fluid loop,
wherein the cooling unit is configured to operate at less than or equal to approximately 42 decibels and the cooling unit has a thermal resistance of less than or equal to 0.30 degrees Celsius per watt.

35. The cooling system of claim 34 wherein the control circuit is configured to regulate a first operation rate of the air mover and a second operation rate of the pump.

36. The cooling system of claim 34 wherein the plurality of fluid lines are configured to input heated fluid into the cooling unit and to output cooled fluid from the cooling unit.

37. The cooling system of claim 34 further comprising a fluid reservoir coupled to the closed fluid loop.

38. The cooling system of claim 34 wherein the cooling unit is configured to operate at less than or equal to approximately 38 decibels.

39. The cooling system of claim 34 wherein the thermal resistance of the cooling unit is less than or equal to approximately 0.20 degrees Celsius per watt.

40. The cooling system of claim 34 wherein the air mover comprises a two-axial blower.

41. The cooling system of claim 40 wherein the two-axial blower is configured to generate a vacuum inside the housing relative to the ambient.

42. The cooling system of claim 40 wherein the two-axial blower includes a first opening on a top surface of the blower and a second opening on a side surface of the blower.

43. The cooling system of claim 42 wherein the blower is configured to draw air into the first opening and to force air out of the second opening.

44. The cooling system of claim 42 wherein the blower is configured to draw air into the second opening and to force air out of the first opening.

45. The cooling system of claim 34 wherein the air mover is separated by at least approximately 25 millimeters from the fluid-to-air heat exchanging device.

46. The cooling system of claim 34 wherein the pump comprises an in-line pump having a pump inlet and a pump outlet configured on opposite sides of the pump.

47. The cooling system of claim 34 wherein the fluid-to-air heat exchanging device comprises a radiator.

48. The cooling system of claim 34 wherein the housing includes vents in a first side proximate the first end of the housing.

49. The cooling system of claim 34 wherein the housing includes a housing opening in a second side proximate the second end of the housing.

50. The cooling system of claim 34 wherein the housing includes a control interface coupled to the control circuit.

51. The cooling system of claim 34 wherein the housing includes a power interface coupled to the air mover, the pump, and the control circuit.

52. The cooling system of claim 34 wherein a height of the air mover is approximately 25 millimeters and the air mover includes an impeller with a diameter of at least approximately 100 millimeters.

53. The cooling system of claim 34 wherein the control circuit is configured to provide pulse width modulation control to the air mover.

54. The cooling system of claim 34 wherein each of the plurality of fluid lines has a water vapor transmission rate of less than or equal to 0.30 grams per centimeter at 65 degrees Celsius.
